(19) United States
(12) Patent Application Publication
(10) Pub. No.: US 2008/0230857 A1
(43) Pub. Date: Sep. 25, 2008

(54) SENSOR CHIP AND SUBSTRATE ASSEMBLY FOR MEMS DEVICE

(75) Inventor: Jeson HSU, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precicion Industries, LTD., Taichung (TW)

(21) Appl. No.: 11/949,183

(22) Filed: Dec. 3, 2007

(30) Foreign Application Priority Data
Mar. 19, 2007 (TW) 96204421

(51) Int. Cl. H01L 29/84

(52) U.S. Cl. 257/415; 257/E29.324

(57) ABSTRACT

A sensor chip and substrate assembly for use in a MEMS device includes a substrate and a sensor chip. The substrate has a top surface, a bottom surface opposite to the top surface, and a passage obliquely penetrating through the top surface and the bottom surface. The sensor chip is mounted on the top surface of the substrate and provided with a sensing zone facing the passage of the substrate. The oblique passage provides a buffering effect to prevent damage to the sensor chip when the quantity of the physical property sending from the detected object increases sharply.

### BACKGROUND OF THE INVENTION

1. Field of the Invention

The present invention relates generally to Micro-Electro-Mechanical System (hereinafter referred to as “MEMS”) devices and more specifically, to a sensor chip and substrate assembly for use in a MEMS device, which includes a substrate having an oblique passage through the top and bottom surfaces thereof, and a sensor chip mounted on the substrate and facing the oblique passage

2. Description of the Related Art

MEMS technology has been intensively used in different fields for different applications. A MEMS device generally comprises a micro electromechanical chip mounted on a substrate, and a cap packaged on the substrate to enclose the micro electromechanical chip. In a sensor chip design (for example, microphone), a vertical passage is provided at the substrate corresponding to the sensor chip for enabling the sensor chip to detect the physical property, such as amplitude and frequency, of, for example, external sound.

FIG. 5 is a sectional view of a conventional MEMS device. According to this design, the MEMS device 40 comprises a substrate 42, which has a passage 48 extending vertically from its top surface 43 to its bottom surface 44, and a sensor chip 41, which is mounted on the substrate 42 and has a sensing zone 46 facing the passage 48 directly.

Because the passage 48 extends in vertical toward the sensing zone of the sensor chip, physical property, such as flow rate of fluid, to be detected may affect the working efficiency of the sensor chip if its value is excessively high, casing damage to the sensor chip or shortening the working life of the sensor chip.

Therefore, it is desirable to provide a sensor chip and substrate assembly that eliminates the aforesaid problem.

### SUMMARY OF THE INVENTION

The present invention has been accomplished under the circumstances in view. It is one objective of the present invention to provide a sensor chip and substrate assembly for use in a MEMS device, which provides a buffering structure to prevent the sensor chip from damage when detecting a physical property having an extremely high quantity.

To achieve above-mentioned objective, the sensor chip and substrate assembly for use in a MEMS device comprises a substrate and a sensor chip mounted on the substrate. The substrate has a top surface, a bottom surface opposite to the top surface, and a passage obliquely penetrating through the top surface and the bottom surface. The sensor chip is mounted on the top surface of the substrate and provided with a sensing zone facing the passage of the substrate for detecting the physical property of an external object through the passage.

By means of the oblique feature of the passage, the physical property, such as pressure, will not be directly transmitted to and impact the sensing zone of the sensor chip so as to protect the sensor chip from damage when detecting the physical property.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic sectional view of a sensor chip and substrate assembly for use in a MEMS device according to an embodiment of the present invention;

FIG. 2 is a schematic partially cutaway view of the sensor chip and substrate assembly according to the embodiment of the present invention;

FIG. 3 is a schematic sectional drawing showing a MEMS device using the sensor chip and substrate assembly according to the embodiment of the present invention;

FIG. 4 is a schematic sectional drawing showing another MEMS device using the sensor chip and substrate assembly according to the embodiment of the present invention; and

FIG. 5 is a schematic sectional view of a MEMS device according to a prior art.

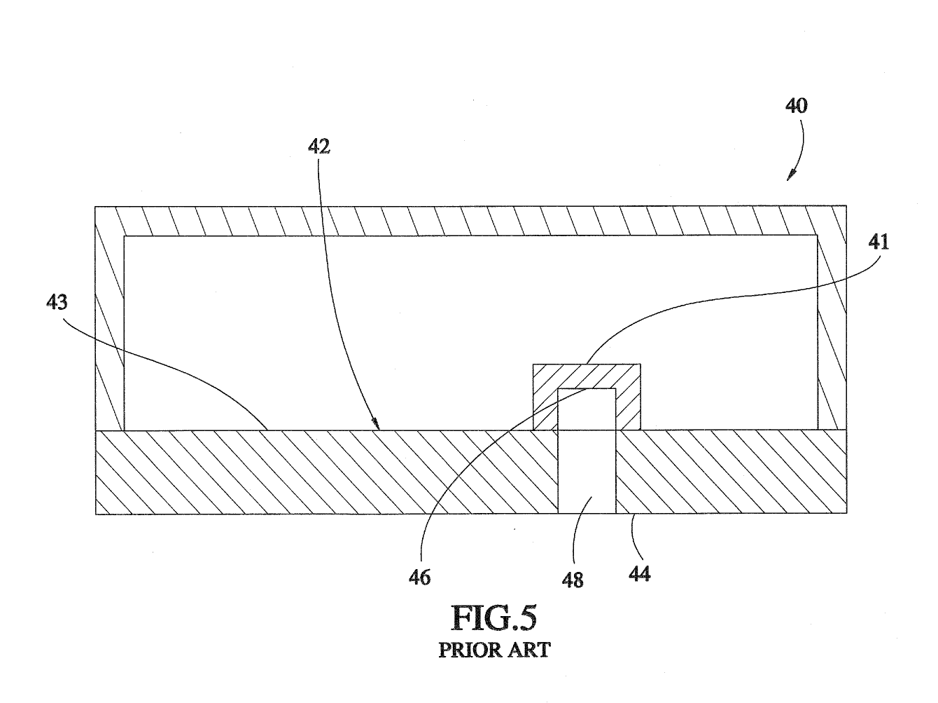

### DETAILED DESCRIPTION OF THE INVENTION

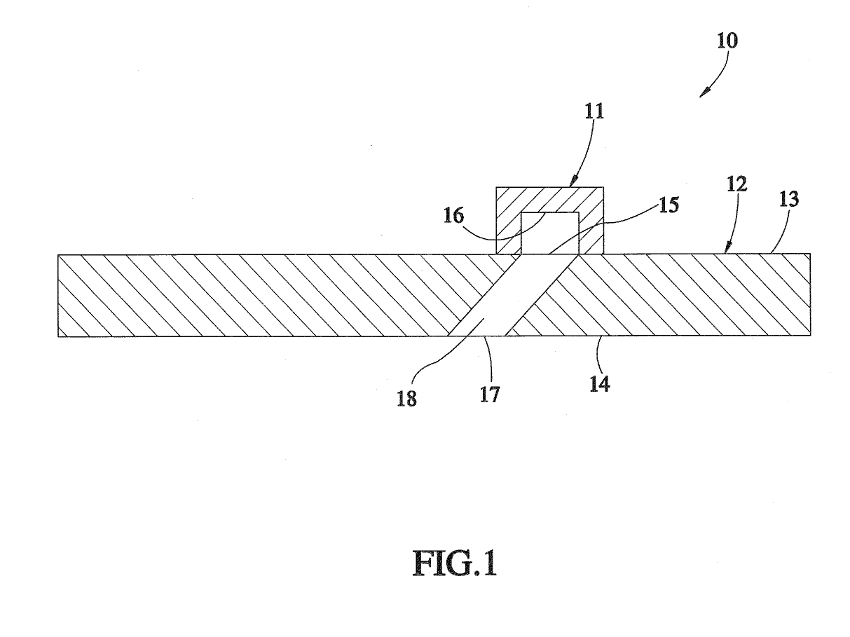

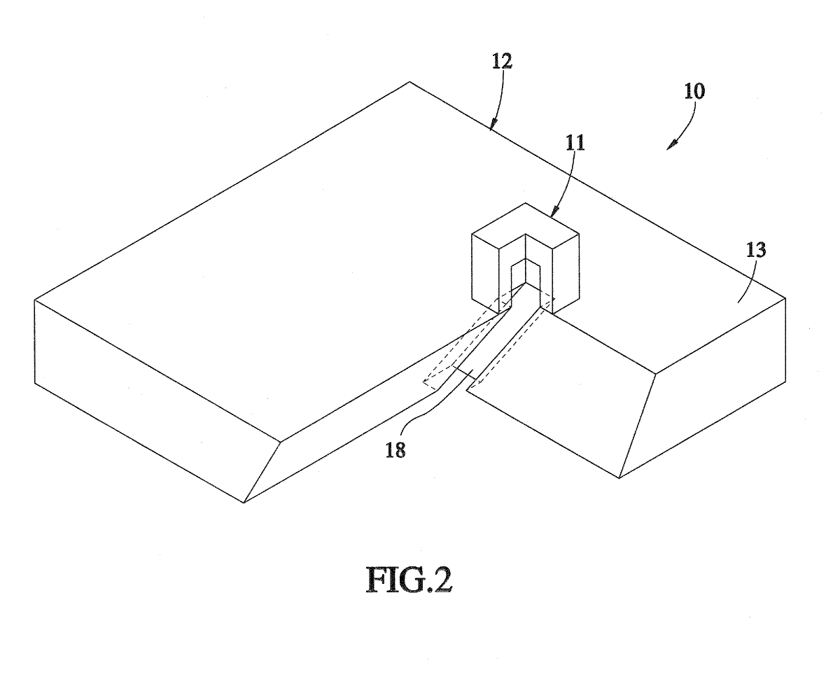

As shown in FIGS. 1 and 2, a sensor chip and substrate assembly 10 adapted to be used in a MEMS device in accordance with an exemplary embodiment of the present invention comprises a substrate 12 and a sensor chip 11.

The substrate 12 has a top surface 13, a bottom surface 14 opposite to the top surface 13, and an oblique passage 18 obliquely extending from the top surface 13 to the bottom surface 14. The oblique passage 18 forms a first opening 15 at the top surface 13 of the substrate 12, and a second opening 17 at the bottom surface 14 of the substrate 12. The axis of the passage 18 defines with the axis extending perpendicular to the plain of the top surface 13 a contained angle, therefore the vertical projection area of the first opening 15 and the vertical projection area of the second opening 17 are not overlapped with each other, or can be partially overlapped with each other.

The sensor chip 11 is mounted on the top surface 13 of the substrate 12 to block the first opening 15 of the passage 18. The sensor chip 11 has a sensing zone 16 facing the first opening 15 of the passage 18.

When the sensor chip 11 detecting a physical property of an external object, the sensing zone 16 of the sensor chip 11 is not directly aimed at the second opening 17 of the passage 18. Therefore, when the value of the physical property of the detected external object increases sharply., the passage 18 can provide a buffering effect, protecting the sensor chip 11 against damage.

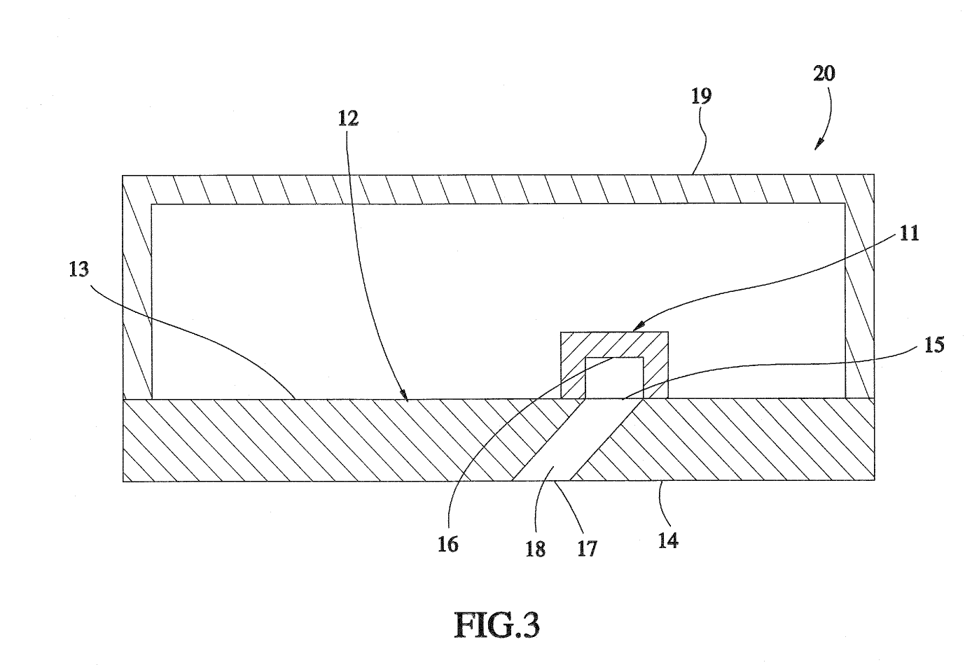

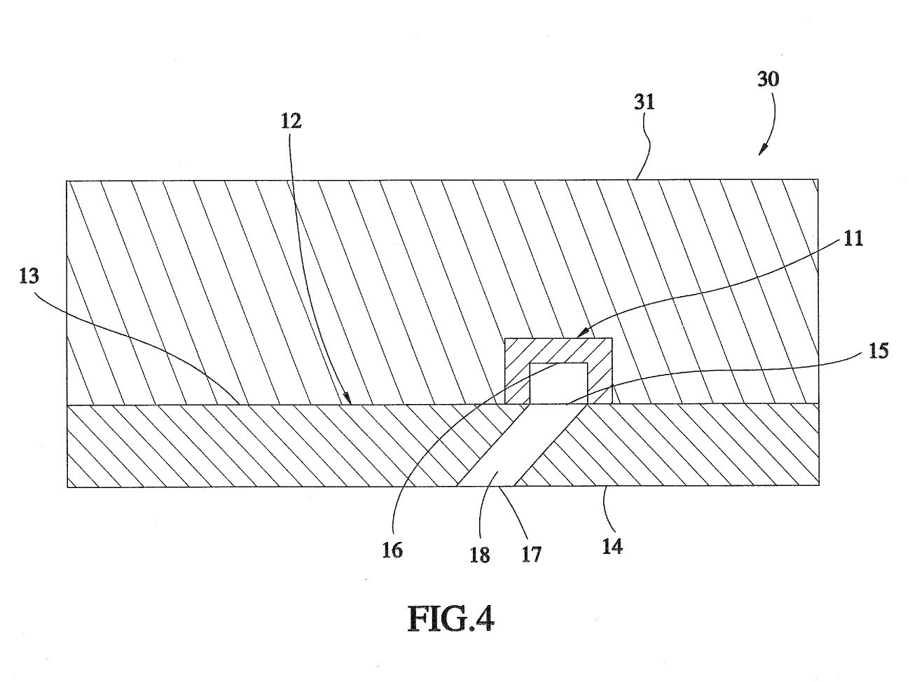

FIG. 3 is a schematic sectional drawing showing a MEMS device 20 using the aforesaid sensor chip and substrate assembly. As shown in FIG. 3, the MEMS device 20 comprises a cap 19 capped on the substrate 12 to protect the sensor chip 11. FIG. 4 is a schematic sectional drawing showing a MEMS device 30 using the aforesaid sensor chip and substrate assembly. As shown in FIG. 4, the MEMS device 30 comprises an encapsulant 31 directly molded on the substrate 12 and encapsulating the sensor chip 11 for protection.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A sensor chip and substrate assembly for use in a MEMS device, comprising:
a substrate having a top surface, a bottom surface opposite to the top surface, and a passage obliquely penetrating through the top surface and the bottom surface; and
a sensor chip mounted on the top surface of the substrate and having a sensing zone facing the passage of the substrate.

2. The sensor chip and substrate assembly as claimed in claim 1, wherein the passage has a first opening formed on the top surface of the substrate and a second opening formed on the bottom surface of the substrate; wherein the vertical projection area of the first opening is not overlapped with the vertical projection area of the second opening.

3. The sensor chip and substrate assembly as claimed in claim 1, wherein the passage has a first opening formed on the top surface of the substrate and a second opening formed on the bottom surface of the substrate; the vertical projection area of the first opening is partially overlapped with the vertical projection area of the second opening.
